(19) United States
(12) Patent Application Publication
(10) Pub. No.: US 2017/0261664 A1
(43) Pub. Date: Sep. 14, 2017

(54) DISPLAY SUBSTRATE, MANUFACTURE METHOD THEREOF, AND TRANSPARENT DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventor: Hongshu ZHANG, Beijing (CN)

(21) Appl. No.: 15/115,450

(22) PCT Filed: Dec. 11, 2015
(86) PCT No.: PCT/CN2015/097099

§ 371 Date: Jul. 29, 2016

(30) Foreign Application Priority Data
Aug. 21, 2015 (CN) 201510520352.4

(51) Int. Cl. G02B 5/28; G02B 5/20; H01L 27/12

(52) U.S. Cl. CPC G02B 5/288; H01L 27/1214; G02B 5/201

(57) ABSTRACT

A display substrate, a manufacture method thereof and a transparent display device are provided. The display substrate includes a substrate (1); a plurality of pixel regions, each including a plurality of sub-pixel regions; and a first metallic layer (3), a passivation layer (5) and a second metallic layer (4) that are formed on the substrate in sequence and are located at the sub-pixel regions. The first metallic layer (3) and the second metallic layer (4) both are transflective metallic layer, and different parts of the passivation layer located at the plurality of sub-pixel regions of a same pixel region have different thicknesses. The first metallic layer (3), the passivation layer (5) and the second metallic layer (4) constitute a Fabry-Perot cavity which allows light having different wavelengths to transmit there-through depending on different thicknesses of different parts of the passivation layer.

### TECHNICAL FIELD

Embodiments of the present invention relate to a display substrate, a manufacture method thereof, and a transparent display device.

### BACKGROUND

A band-pass refers to a filter in which a smaller, middle portion of a certain waveband is a passband with high transmittance and two sides of the passband is a cutoff band with high reflectivity.

### SUMMARY

Embodiments of the present invention provide a display substrate, a manufacture method thereof, and a transparent display device.

An embodiment of the present invention provides a display substrate, including: a substrate; a plurality of pixel regions each including a plurality of sub-pixel regions; and a first metallic layer, a passivation layer and a second metallic layer which are disposed on the substrate display in sequence and are located at the sub-pixel regions. The first metallic layer and the second metallic layer both are transflective metallic layer. Different parts of the passivation layer located at the plurality of sub-pixel regions of a same pixel region have different thicknesses. The first metallic layer, the passivation layer and the second metallic layer constitute a Fabry-Perot cavity which allows light having different wavelengths to transmit there-through depending on a thickness of the passivation layer.

In an example, each of the pixel regions includes three sub-pixel regions; different parts of the passivation layer corresponding to the three sub-pixel regions has a first thickness, a second thickness and a third thickness, respectively; and the sub-pixel region corresponding to a first part of the passivation layer having the first thickness allows red light to transmit there-through, the sub-pixel region corresponding to a second part of the passivation layer having the second thickness allows green light to transmit there-through, and the sub-pixel region corresponding to a third part of the passivation layer having the third thickness allows blue light to transmit there-through.

In an example, the thickness of the passivation layer satisfies a formula of d=m*λ/2n; where m is an odd number, n is a refractive index of the passivation layer, λ is a wavelength of light which is allowed to transmit through the sub-pixel region corresponding to the part of the passivation layer having the thickness.

In an example, the second metallic layer is made of silver, and the second metallic layer has a thickness of 35˜45 nm.

In an example, the passivation layer is made of any material selected from a group consisting of MgF₂, SiO₂, Si₃N₄ and TiO₂.

In an example, the first metallic layer is made of silver, and the first metallic layer has a thickness of 35˜45 nm.

In an example, the second metallic layer includes a plurality of metallic ribs arranged at intervals, and the plurality of metallic ribs are provided with slits there-between which allow light to transmit there-through.

An embodiment of the present invention also provides a manufacture method of display substrate, including: providing a substrate; forming a first metallic layer in a pixel region on the substrate; forming a passivation layer on the first metallic layer such that the different parts of the passivation layer located at a plurality of sub-pixels of a same pixel region have different thicknesses; forming a second metallic layer on the passivation layer, wherein the first metallic layer, the passivation layer and the second metallic layer constitute a Fabry-Perot cavity which allows light having different wavelengths to transmit there-through depending on thicknesses of different parts of the passivation layer.

In an example, forming of the passivation layer on the first metallic layer such that different parts of the passivation layer located at a plurality of sub-pixels of a same pixel region have different thicknesses includes: by using a same mask, depositing a passivation layer having a first thickness at a first location for a time period t1; depositing a passivation layer having a second thickness at a second location for a time period t2; and depositing a passivation layer having a third thickness at a third location for a time period t3.

In an example, the thickness of the passivation layer satisfies a formula of d=m*λ/2n; where m is an odd number, n is a refractive index of the passivation layer, λ is a wavelength of light which is allowed to transmit through the sub-pixel region corresponding to the passivation layer having the thickness.

In an example, the passivation layer is made of any material selected from a group consisting of MgF₂, SiO₂, Si₃N₄ and TiO₂

In an example, the second metallic layer includes a plurality of metallic ribs arranged at intervals, and the plurality of metallic ribs are provided with slits there-between which allow light to transmit there-through.

An embodiment of the present invention further provide a transparent display device including the display substrate.

### BRIEF DESCRIPTION OF THE DRAWINGS

FIG. 1 is a schematic diagram illustrating characteristics of a band-pass filter;

FIG. 2 is a schematically structural diagram illustrating a display substrate provided by an embodiment of the present invention;

FIGS. 3a-3e are flow charts illustrating a manufacture process of the display substrate provided by embodiments of the present invention;

FIGS. 4a-4c are flow charts illustrating a manufacture process of a passivation layer provided by embodiments of the present invention.

### DETAILED DESCRIPTION

Technical solutions according to the embodiments of the present disclosure will be described clearly and understandable as below in conjunction with the accompanying drawings of embodiments of the present disclosure. It is apparent that the described embodiments are only a part of but not all of exemplary embodiments of the present disclosure. Based on the described embodiments of the present disclosure, various other embodiments can be obtained by those of ordinary skill in the art without creative labor and those embodiments shall fall into the protection scope of the present disclosure.

Unless otherwise defined, all the technical and scientific terms used herein have the same meanings as commonly understood by one of ordinary skill in the art to which the present invention belongs. The terms, such as “first,” “second,” or the like, which are used in the description and the claims of the present application, are not intended to indicate any sequence, amount or importance, but for distinguishing various components. Also, the terms, such as “a/an,” “the,” or the like, are not intended to limit the amount, but for indicating the existence of at lease one. The terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the position of the object which is described is changed, the relative position relationship may be changed accordingly.

The inventors have realized that a band-pass filter can include two structure ways, one of which is to form a passband of the band-pass filter by using an overlapped, band-pass waveband between a long-wave-pass film system and a short-wave-pass film system. Such structure can obtain a spectral characteristic that a relatively wider cutoff band and a relatively larger cutoff depth are easily available but a relatively narrower passband is difficult to achieve, and it is usually used to fabricate broadband pass filters. The other way is to form a color filter film system by a Fabry-Perot interferometer. Such structure can obtain a spectral characteristic that a relatively narrower passband is available but normally the cutoff band is also relatively narrower with smaller cutoff depth, and has to be utilized in cooperation with a cut off filter to expand the cutoff band and increase the cutoff depth in most cases. Therefore, a light transmittance of the band-pass filter as provided is relatively lower, and incorporating a color filter into a transparent display device may result in a relatively complicated structure of the entire display device which requires much more manufacture processes and impacts a manufacture efficiency of the display device.

Embodiments of the present invention provide a display substrate, a manufacture method thereof and a transparent display device, to achieve a relatively narrower color gamut and a relatively higher transmittance. According to technical solutions of the present invention, by filtering light through different parts of a passivation layer and by transmitting the light through slits provided between second metallic layers, the transmittance of the display substrate is improved. The technical solutions of the present invention will be described in more details as below in conjunction with the accompanying drawings and particular embodiments for better understanding.

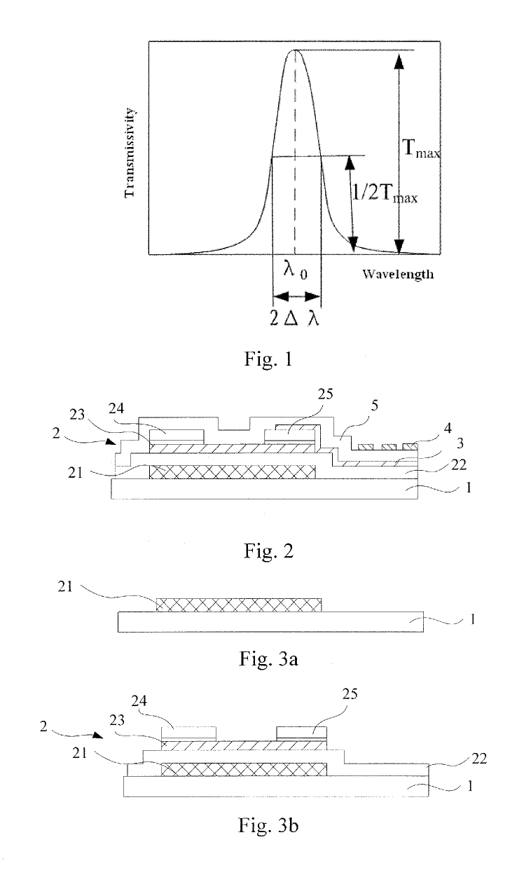

FIG. 1 illustrates main parameters representing properties of a filter, where λ₀ is a central wavelength or a peak wavelength; Tₘₐₓ is a transmittance (transmissivity) at the central wavelength, also referred to as peak-transmittance; 2Δλ is a wavelength width at which the transmittance is one half of the peak-transmittance, also referred to as half width of passband, or 2Δλ/λ₀ is a relative half-width.

As illustrated in FIG. 2 and FIG. 4c, FIG. 2 is a schematically structural diagram illustrating a display substrate provided by an embodiment of the present invention, and FIG. 4c is a schematically structural diagram illustrating a passivation layer 5 as formed, respectively.

Embodiments of the present invention provide a display substrate, including: a substrate; a plurality of pixel regions, each including a plurality of sub-pixel regions. A first metallic layer, a passivation layer and a second metallic layer are disposed on the substrate in sequence and are located at the sub-pixel regions. The first metallic layer and the second metallic layer both are transflective metallic layer, and different parts of the passivation layer located at the plurality of sub-pixel regions of a same pixel region have different thicknesses.

The first metallic layer, the passivation layer and the second metallic layer constitute a Fabry-Perot cavity. The Fabry-Perot cavity allows light having different wavelengths to transmit there-through depending on different thickness of different parts of the passivation layer.

In the technical solutions of the present invention, a Fabry-Perot cavity is constituted by using a first metallic layer 3, a second metallic layer 4 and a passivation layer 5 which has different thicknesses in different parts; the Fabry-Perot cavity allows light having different wavelengths to transmit there-through depending on different thicknesses of different parts of the passivation layer 5, so that the display device has no need of using a color filter, and it can allow light having different wavelengths to transmit there-through by structures on the display substrate directly, which simplifies a structure of the display device and transparent display is also be realized.

Hereafter structures and principles of the display device provided by the embodiments of the present invention are described as below in conjunction with exemplary embodiments for convenience of understanding.

In the present embodiment, each of the pixel regions includes three sub-pixel regions; different parts of the passivation layer corresponding to the three sub-pixel regions have a first thickness, a second thickness and a third thickness, respectively. A first part of the passivation layer having the first thickness allows red light to transmit there-through, A second part of the passivation layer having the second thickness allows green light to transmit there-through, and A third part of the passivation layer having the third thickness allows blue light to transmit there-through.

It should be understood that, a non-display region on the display substrate provided by the present embodiment is also provided with a thin film transistor 2. The thin film transistor 2 includes a gate electrode 21; a gate insulating layer 22 disposed on the gate electrode 21; an active layer 23 disposed on the gate insulating layer 22; and a source electrode 24 and a drain electrode 25 which are disposed on the active layer 23. A channel is disposed between the source electrode 24 and the drain electrode 25. The first metallic 3 and the drain electrode 25 are disposed in a same layer, and the passivation layer 5 covers the source electrode 24 and the drain electrode 25.

The display substrate provided by embodiments of the present invention follows a working principle of the Fabry-Perot cavity. The Fabry-Perot cavity is constituted by two metallic layers and a dielectric layer disposed between the two metallic layers. The two metallic layers can achieve transflective function. A transmittance of the Fabry-Perot cavity is represented in a formula as T=Iₜ/Iₜ=T₀/(1+F sin² θ) where

$${T}_{0} = \frac{{T}_{1} {T}_{2}}{{( 1 - {R}_{1} {R}_{1} )}^{2}} , \\ F = \frac{4 \sqrt{{R}_{1} {R}_{2}}}{{( 1 - \sqrt{{R}_{1} {R}_{2}} )}^{2}} , \\ θ = \frac{1}{2} ( {ϕ}_{1} + {ϕ}_{2} - 2 δ ) ;$$

in the formula, R₁, R₂, T₁ and T₂ are representatives of a reflectivity and a transmittance of the two metallic layers, respectively; φ₁ and φ₂ are representatives of reflection-induced retardances of the metallic layers, respectively; and

$$δ = \frac{2 π}{λ} nd$$

is representative of a phase thickness of the dielectric layer. That is, the transmittance of the Fabry-Perot cavity can be changed by arranging the phase thickness of the dielectric layer so that a wavelength of the light allowed to transmit through the Fabry-Perot cavity is changed. In this way, light beam of the white light varies in its color upon transmitting through the Fabry-Perot cavity.

On the basis of the above principle, the display substrate provided by the present embodiment utilizes the first metallic layer 3 and the second metallic layer 4 as the metallic layer, and utilizes the passivation layer 5 as the dielectric layer, so as to form a Fabry-Perot cavity by the first metallic layer 3, the passivation layer 5 and the second metallic layer 4 which are formed at the pixel regions on the display substrate. In this way, the display substrate can selectively allow light to transmit there-through. During the preparing process, the passivation layer 5 is formed into different parts of different thicknesses, including a first part of the passivation layer 51 having a first thickness, a second part of the passivation layer 52 having a second thickness and a third part of the passivation layer 53 having a third thickness. The different parts of the passivation layer 5 having three different thicknesses, together with corresponding first metallic layer 3 and second metallic layer 4, constitute a Fabry-Perot cavity which allows the light having three different wavelengths to transmit there-through, that is, the red light, green light and blue light, so as to achieve a selective light transmittance of the display substrate.

The passivation layer 5 is directly formed on the first metallic layer 3 by a PECVD process. The passivation layer 5 as formed can have different thicknesses satisfying a formula of d=m*λ/2n by adopting different depositing times; where m is an odd number, n is a refractive index of the passivation layer, λ is a wavelength of the light which is allowed to transmit through the sub-pixel region corresponding to a part of the passivation layer having a thickness. For example, the red light corresponds to a wavelength of 760˜622 nm, the blue light corresponds to a wavelength of 450˜435 nm, and the green light corresponds to a wavelength of 577˜492 nm. Correspondingly, the first part of the passivation layer 51 having the first thickness as formed satisfies a formula of d1=m*700 nm/2n. For example, given that m=1 and n=1.938 (a refractive index of Si₃N₄, usually 1.3˜2.1, herein it is selected as 1.938), then the thickness of the first part of the passivation layer corresponding to a R pixel is d1=180.6 nm. Similarly, the thickness of the second part of the passivation layer corresponding to a G pixel and the thickness of the third part of the passivation layer corresponding to a B pixel are d2=140.9 nm and d3=12.4 nm, respectively. Moreover, the passivation layer 5 can be made of any material selected from a group consisting of MgF₂, SiO₂, Si₃N₄, TiO₂ and the like. For example, the passivation layer 5 is made of Si₃N₄. Furthermore, during a manufacture process, different parts of the passivation layer 5 having three different thicknesses can be disposed at different locations to correspond to red sub-pixel, blue sub-pixel and green sub-pixel, respectively.

The first metallic layer 3 and the second metallic layer 4 provided by the present embodiments have transflective function, and both can be made of various metals to achieve the above function. For example, both the first metallic layer 3 and the second metallic layer 4 can be made of silver material, and the first metallic layer 3 and the second metallic layer 4 as formed both can have a thickness in a range of 35˜45 nm, such as 35 nm, 38 nm, 40 nm, 42 nm and 45 nm, so as to allow a better transmittance performance of the first metallic layer 3 and the second metallic layer 4.

The second metallic layer 4 includes a plurality of metallic ribs arranged at intervals, and the plurality of metallic ribs are provided with slits there-between. That is, the second metallic layer 4 is formed into portions which are arranged at intervals or spaced apart from each other, and adjacent metallic ribs are provided with a slit there-between. In the operation, the passivation layer 5 and the first metallic layer 3 that are disposed corresponding to the slits between metallic ribs cannot constitute a Fabry-Perot cavity due to the missing of the second metallic layer 4; as a result, the first metallic layer 3 and the passivation layer 5 that are corresponding to the slits cannot play a role of filtering the light, which allow white light to transmit through the slits. Moreover, the light reflected by the second metallic layer 4 (i.e., the light that cannot transmit through the second metallic layer 4) is propagated within the passivation layer 5 to reach the locations of the slits and transmits through the slits, so as to increase the coefficient of the utilization of the light and improve the transmittance of the entire transparent display device.

Based on the above description, it can be seen that the display substrate provided by the present embodiment constitutes a Fabry-Perot cavity by using a first metallic layer 3, a second metallic layer 4, and a passivation layer 5 having different thicknesses in different parts, to achieve a relatively narrower color gamut, and, by arranging slits between portions of the second metallic layer 4, the transmittance of the entire transparent display device is effectively increased.

Embodiments of the present invention also provide a manufacture method of display substrate, comprising steps of: providing a substrate; forming a first metallic layer in a pixel region on the substrate; forming a passivation layer on the first metallic layer such that the passivation layer located at a plurality of sub-pixels of a same pixel region has different thicknesses in different parts; forming a second metallic layer on the passivation layer. The first metallic layer, the passivation layer and the second passivation layer constitute a Fabry-Perot cavity which allows light having different wavelengths to transmit there-through depending on a thickness of a part of the passivation layer.

With the manufacture method of display substrate provided by the embodiments of the present invention, the display substrate as manufactured allows light of different colors to transmit there-through. The manufacture method of display substrate provided by embodiments of the present invention will be described in details as below in conjunction with the accompanying drawings and exemplary embodiments for convenience of understanding.

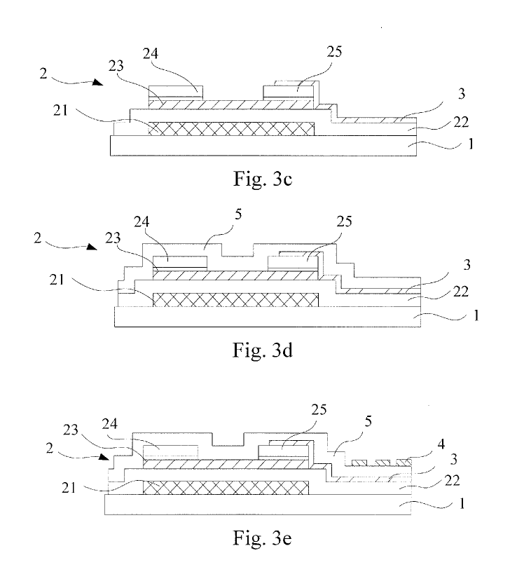

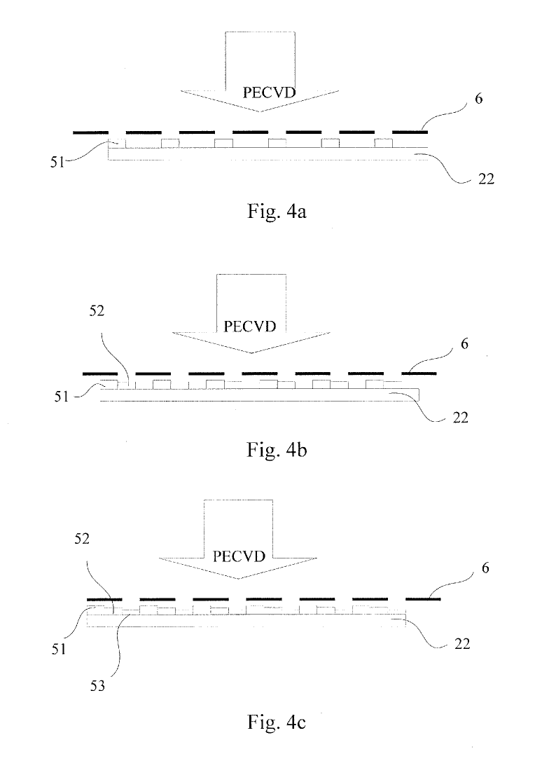

Step S1, forming a thin film transistor (TFT) 2 on a substrate 1, as illustrated in FIG. 3a and FIG. 3b.

For example, as illustrated in FIG. 3, firstly, forming a gate electrode 21 on the substrate 1; then, as illustrated in FIG. 3b, forming a gate insulating layer 22 on the gate electrode 21, forming an active layer 23 on the gate insulating layer 22, and forming a source electrode 24 and a drain electrode 25 on the active layer 23.

Step S2, forming a first metallic layer 3 at a location in a pixel region on the substrate, as illustrated in FIG. 3c.

For example, as illustrated in FIG. 3c, forming the first metallic layer 3 on the TFT 2 by an etching process. The first metallic layer 3 can be made of silver material and has a thickness of 40 nm, for example.

Step S3, forming a passivation layer on the first metallic layer such that the passivation layer located at the plurality of sub-pixel regions of a same pixel region has different thicknesses in different parts.

For example, as illustrated in FIGS. 4a-4c, the passivation layer 5 as formed includes a first part of passivation layer 51 having a first thickness, a second part of passivation layer 52 having a second thickness, and a third part of passivation layer 53 having a third thickness.

By using a same mask 6, as illustrated in FIG. 4a, depositing a first part of the first passivation layer 51 having the first thickness d1 at a first location for a time period t1; as illustrated in FIG. 4b, depositing a second part of the second passivation layer 52 having the second thickness d2 at a second location for a time period t2; and as illustrated in FIG. 4c, depositing a third part of the passivation layer 53 having the third thickness d3 at a third location for a time period t3.

During preparation, given a same depositing velocity, the thicknesses of the passivation layer of different parts as formed are controlled by controlling the time period t1, t2 and t3 of deposition.

For example, forming the passivation layer 5 having different thicknesses in different parts on the first metallic layer 3 by using a PECVD process. For example, different parts of the passivation layer corresponding to R, G and B sub-pixels have different thicknesses, respectively. For example, the thickness of the passivation layer satisfies d=m*λ/2n, where m is an odd number, n is a refractive index of the passivation layer, λ is a wavelength of light which is allowed to transmit through the sub-pixel region corresponding to the passivation layer having the thickness. For example, the red light corresponds to a wavelength of 760˜622 nm, the blue light corresponds to a wavelength of 450˜435 nm, and the green light corresponds to a wavelength of 577˜492 nm. Correspondingly, during the manufacture process of the passivation layer, the first part of the passivation layer 51 having the first thickness satisfies a formula of d1=m*700 nm/2n. For example, given that m=1 and n=1.938 (a refractive index of Si₃N₄, usually 1.3˜2.1, herein it is selected as 1.938), then the thickness of the first part of the passivation layer corresponding to a R pixel is d1=180.6 nm. Similarly, the thickness of the second part of the passivation layer 5 corresponding to a G pixel and the thickness of the third part of the passivation layer 5 corresponding to a B pixel are d2=140.9 nm and d3=12.4 nm, respectively. Moreover, the passivation layer 5 can be made of any material selected from a group consisting of MgF₂, SiO₂, Si₃N₄, TiO₂ and the like. For example, the passivation layer 5 is made of Si₃N₄; Furthermore, during a manufacture process, the passivation layer 5 having three different thicknesses in different parts can be disposed at different locations. The passivation layer 5 having three different thicknesses in different parts correspond to red sub-pixel, blue sub-pixel and green sub-pixel, respectively.

Step S4, as illustrated in FIG. 3e, forming a second metallic layer on the passivation layer, and the first metallic layer, the passivation layer and the second metallic layer constitute a Fabry-Perot cavity which allows light having different wavelengths to transmit there-through depending on the thickness of the passivation layer.

For example, as illustrated in FIG. 3e, forming a second metallic layer 4 on the passivation layer 5 as formed, and the second metallic layer 4 has slits. An amount of the slits and a value of W/S (where W is the metal, S is the slit) are determined depending on a pixel pitch. For example, given that the pixel pitch is 53.7 nm, the amount of the slits can be 5 and the value of W/S can be 2.7/5.0 nm. The second metallic layer can be made of silver material and has a thickness of 40 nm.

Embodiments of the present invention also provide a transparent display device comprising the display substrate.

According to the technical solutions of the present invention, a Fabry-Perot cavity is constituted by a first metallic layer, a passivation layer having different thicknesses in different parts and a second metallic layer, the Fabry-Perot cavity allows light having different wavelengths to transmit there-through depending on the thicknesses of the passivation layer in different parts, so that the display device can allow the light having different wavelengths to transmit there-through by structures formed on the display substrate directly, without the need of using a color filter film, which simplifies the structure of the display device, improves the manufacture efficiency and achieves transparent display.

The described above are only exemplary embodiments of the present disclosure, and the present disclosure is not intended to limited thereto. For one of ordinary skill in the art, various modifications and improvements may be made without departing from the spirit and scope of embodiments of the present disclosure, and all of these modifications and improvements shall fall within the scope of the present invention.

The present application claims benefits of Chinese patent application 201510520352.4 filed on Aug. 21, 2015 and entitled “a display substrate, a manufacture method thereof and a transparent display device”, the contents of which are incorporated herein by reference.

1. A display substrate, comprising:
a substrate;
a plurality of pixel regions, each including a plurality of sub-pixel regions; and
a first metallic layer, a passivation layer and a second metallic layer that are formed on the substrate in sequence and are located at the sub-pixel regions,
wherein the first metallic layer and the second metallic layer both are transreflective metallic layer, and different parts of the passivation layer located at the plurality of sub-pixel regions of a same pixel region have different thicknesses, and
the first metallic, the passivation layer and the second metallic layer constitute a Fabry-Perot cavity which allows light having different wavelengths to transmit there-through depending on different thicknesses of different parts of the passivation layer.

2. The display substrate according to claim 1, wherein, each of the pixel regions comprises three sub-pixel regions; different parts of the passivation layer corresponding to the three sub-pixel regions has a first thickness, a second thickness and a third thickness, respectively; and a first part of the passivation layer having the first thickness corresponds to a sub-pixel region which allows red light to transmit there-through, a second part of the passivation layer having the second thickness corresponds to a sub-pixel region which allows green light to transmit there-through, and a third part of the passivation layer having the third thickness corresponds to a sub-pixel region which allows blue light to transmit there-through.

3. The display substrate according to claim 2, wherein each of the thicknesses of the passivation layer of different parts satisfies a formula of d=m*λ/2n; where, m is an odd number, n is a refractive index of the passivation layer, λ is a wavelength of light being allowed to transmit through the sub-pixel region corresponding to the passivation layer having the thickness.

4. The display substrate according to claim 1, wherein the second metallic layer is made of silver, and the second metallic layer has a thickness of 35˜45 nm.

5. The display substrate according to claim 1, wherein the passivation layer is made of any material selected from a group consisting of MgF₂, SiO₂, Si₃N₄ and TiO₂.

6. The display substrate according to claim 1, wherein the first metallic layer is made of silver, and the first metallic layer has a thickness of 35˜45 nm.

7. The display substrate according to claim 1, wherein the second metallic layer comprises a plurality of metallic ribs arranged at intervals, and the plurality of metallic ribs are provided with slits there-between which allow light to transmit there-through.

8. A manufacture method of display substrate, comprising:
providing a substrate;
forming a first metallic layer in a pixel region on the substrate;
forming a passivation layer on the first metallic layer so that different parts of the passivation layer located at a plurality of sub-pixels of a same pixel region have different thicknesses; and
forming a second metallic layer on the passivation layer, wherein the first metallic layer, the passivation layer and the second passivation layer constitute a Fabry-Perot cavity, the Fabry-Perot cavity allowing light having different wavelengths to transmit there-through depending on thicknesses of different parts of the passivation layer.

9. The manufacture method of display substrate according to claim 8, wherein forming of the passivation layer on the first metallic layer so that different parts of the passivation layer located in the plurality of sub-pixels of the same pixel region have different thicknesses comprises: by using a same mask,
depositing a first part of passivation layer having a first thickness at a first location for a time period t1;
depositing a second part of the passivation layer having a second thickness at a second location for a time period t2; and
depositing a third part of the passivation layer having a third thickness at a third location for a time period t3.

10. The manufacture method of display substrate according to claim 9, wherein the thickness of each part of the passivation layer satisfies a formula of d=m*λ/2n; where, m is an odd number, n is a refractive index of the passivation layer, λ is a wavelength of light allowed to transmit through the sub-pixel region corresponding to the part of the passivation layer having the thickness.

11. The manufacture method of display substrate according to claim 8, wherein the passivation layer is made of any material selected from a group consisting of MgF₂, SiO₂, Si₃N₄ and TiO₂.

12. The manufacture method of display substrate according to claim 8, wherein the second metallic layer comprises a plurality of metallic ribs arranged at intervals, and the plurality of metallic ribs are provided with slits there-between which allow light to transmit there-through.

13. A transparent display device, comprising the display substrate according to claim 1.

14. The display substrate according to claim 1, wherein each of the thicknesses of the passivation layer of different parts satisfies a formula of d=m*λ/2n; where, m is an odd number, n is a refractive index of the passivation layer, λ is a wavelength of light being allowed to transmit through the sub-pixel region corresponding to the passivation layer having the thickness.

15. The display substrate according to claim 2, wherein the second metallic layer is made of silver, and the second metallic layer has a thickness of 35˜45 nm.

16. The display substrate according to claim 15, wherein the passivation layer is made of any material selected from a group consisting of MgF₂, SiO₂, Si₃N₄ and TiO₂.

17. The display substrate according to claim 16, wherein the second metallic layer comprises a plurality of metallic ribs arranged at intervals, and the plurality of metallic ribs are provided with slits there-between which allow light to transmit there-through.

18. The manufacture method of display substrate according to claim 8, wherein the thickness of each part of the passivation layer satisfies a formula of d=m*λ/2n; where, m is an odd number, n is a refractive index of the passivation layer, λ is a wavelength of light allowed to transmit through the sub-pixel region corresponding to the part of the passivation layer having the thickness.

19. The manufacture method of display substrate according to claim 9, wherein the passivation layer is made of any material selected from a group consisting of MgF₂, SiO₂, Si₃N₄ and TiO₂.

20. The manufacture method of display substrate according to claim 9, wherein the second metallic layer comprises a plurality of metallic ribs arranged at intervals, and the plurality of metallic ribs are provided with slits there-between which allow light to transmit there-through.
